(19) United States
(12) Patent Application Publication
(10) Pub. No.: US 2008/0122042 A1
(43) Pub. Date: May 29, 2008

(54) APPLICATIONS OF POLYCRYSTALLINE WAFERS

(76) Inventors: Michael Goldstein, Sunnyvale, CA (US); Irwin Yablok, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/563,626

(22) Filed: Nov. 27, 2006

(51) Int. Cl. H01L 27/12; H01L 21/84

(52) U.S. Cl. 257/629; 438/459; 257/E27.112; 257/E21.704

(57) ABSTRACT

A wafer comprising polycrystalline silicon is used in various applications, including as a handling wafer, a test wafer, a dummy wafer, or as a substrate in a bonded die. Use of polycrystalline material instead of single-crystal may lower expenses.

### BACKGROUND

### Background of the Invention

Most integrated circuits today are formed on single-crystal silicon wafers. Single-crystal silicon wafers are used as mechanical handling wafers, test wafers, and dummy wafers in semiconductor processing operations. However, the supply of single-crystal silicon ingots and wafers is limited, making them expensive.

### BRIEF DESCRIPTION OF THE DRAWINGS

FIG. 1a is a top view that illustrates a wafer comprising a polycrystalline material.

FIG. 1b is a cross sectional side view that illustrates the same wafer.

FIGS. 2 and 3 are top views that illustrate composite wafers and that have a polycrystalline portion and a single crystal portion.

FIG. 4 is a flow chart that describes one possible way to make a composite wafer.

FIG. 5 is a flow chart that describes one use to which the composite wafer can be put.

FIG. 6 is a flow chart that illustrates another use to which polycrystalline wafers may be put: as a substrate in a bonded device.

FIGS. 7a-7d are cross sectional side views that illustrate this bonding

FIG. 8a is a cross sectional side view that illustrates one embodiment of a die with devices formed on the bonded wafer.

FIG. 8b is a top view of the die of FIG. 8a.

### DETAILED DESCRIPTION

In various embodiments, wafers at least partially comprising polysilicon are used in semiconductor processing in situations where previously single crystal silicon wafers were used. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

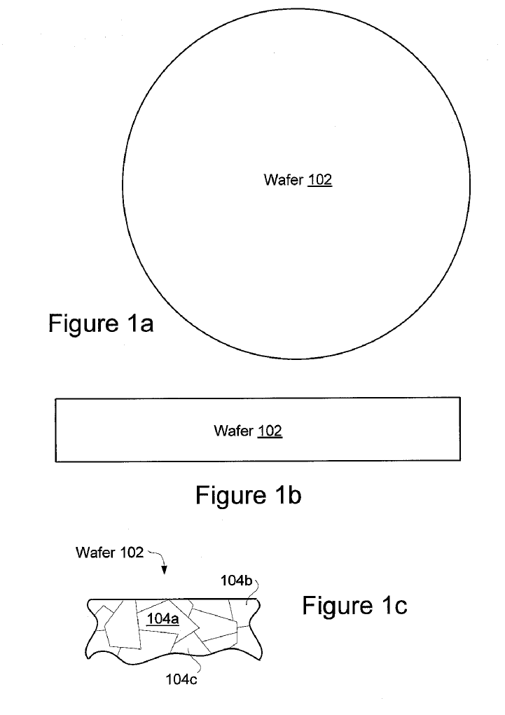

FIG. 1a is a top view that illustrates a wafer 102 comprising a polycrystalline material. FIG. 1b is a cross sectional side view that illustrates the same wafer 102. The wafer 102 is substantially entirely polycrystalline material in an embodiment. In an embodiment, the wafer 102 is substantially entirely polysilicon. In other embodiments, there may be portions of the wafer 102 that are a polycrystalline material such as polysilicon, while other substantial regions of the wafer 102 may be a single crystal material, such as single crystal silicon. As illustrated, the wafer 102 has a substantially circular shape. The wafer 102 may have a diameter of 200 mm, 300 mm, 450 mm or other sizes. The wafer 102 may have other non-circular shapes and/or other sizes in other embodiments.

FIG. 1c is a cross sectional view that illustrates a portion of the wafer 102 in greater detail than shown in FIGS. 1a and 1b. As seen in FIG. 1c, the wafer 102 includes a number of crystal grains 104, such as grain 104a, grain 104b, grain 104c, etc. There are grain boundaries between the grains 104. Each grain 104 may have its own crystal orientation, which may be different than the orientation of adjoining grains 104.

As mentioned above, substantially the entire wafer 102 may be of this polycrystalline structure. Such a wafer 102 may be formed by sintering. Silicon powder may be brought together at a heat and temperature determined by desired properties (such as grain size) of the wafer 102 to form an ingot. The ingot may then be sliced, with the slices being polished to form multiple wafers 102. As such a sintering operation may be simpler and cheaper than the growth of an ingot of single crystal material, the wafer 102 may thus be less expensive and more readily available than single crystal wafers.

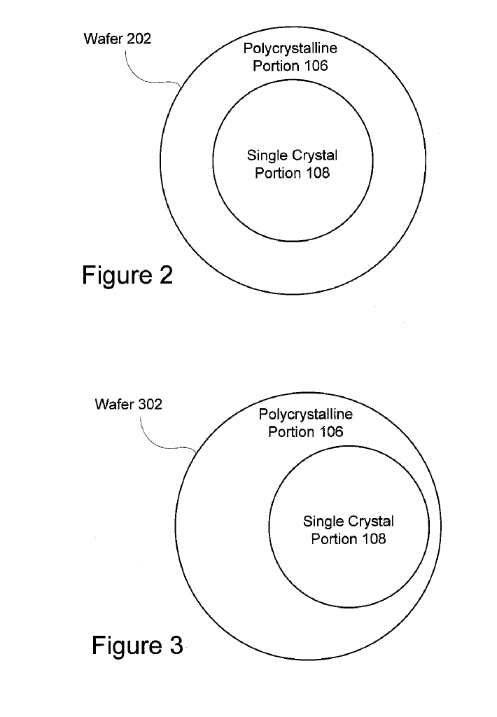

FIGS. 2 and 3 are top views that illustrate composite wafers 202 and 302 that have a polycrystalline portion 106 and a single crystal portion 108. In this document, the term “composite wafer” means a wafer with a polycrystalline portion 106 and a single crystal portion 108, in which the single crystal portion 108 takes up at least 15% of the volume of the wafer 202, 302. In some embodiments, the single crystal portion 108 may take up 25%, 30%, 40%, 50% or even more of the volume of the wafer 202, 302. In an embodiment, the single crystal portion 108 takes up between about 42% and 46% of the volume of the wafer 202, 302. The polycrystalline portion 106, may make up substantially all of the rest of the wafer. In an embodiment, the single crystal portion 108 takes up between about 42% and 46% of the volume of the wafer 202, 302, while the polycrystalline portion 106 takes up between about 58% and 54% of the volume. The diameters of the single crystal portion 108 and polycrystalline portion 106 may be any that is desired, such as a 200 mm single crystal portion 108 within a 450 mm polycrystalline portion 106, a 300 mm single crystal portion 108 within a 450 mm polycrystalline portion 106, 450 mm single crystal portion 108 within a 600 mm polycrystalline portion 106, or other sizes.

In the embodiment illustrated in FIG. 2, the wafer 202 includes a substantially circular single crystal portion 108 that is approximately centered within a substantially circular polycrystalline portion 106. In the embodiment illustrated in FIG. 3, the wafer 302 includes a substantially circular single crystal portion 108 that is offset from the center of a substantially circular polycrystalline portion 106, so that the single crystal portion 108 extends from the center of the wafer 302 almost to an outside edge. The single crystal portion 108 in each of wafers 202 and 302 extends through the entire thickness of the wafer 202, 302. In other embodiments, the single crystal portion 108 may not extend through the entire thickness, may have a different shape that that of the polycrystalline portion 106, and/or may not be completely surrounded by the polycrystalline portion 106 (may be at or adjacent an edge of the wafer). In yet other embodiments, there may be more than one single crystal portion 108 within the polycrystalline portion 106, such as two 200 mm diameter circular single crystal portions 108 within a 450 mm diameter polycrystalline portion 106. Various other arrangements of composite wafers are also possible.

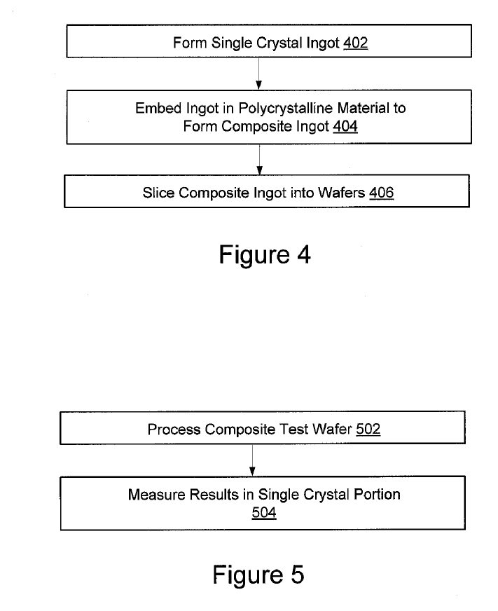

FIG. 4 is a flow chart that describes one possible way to make a composite wafer 202, 302 such as those shown in FIGS. 2 and 3. First, a single crystal ingot is formed 402. This ingot may be a single crystal silicon ingot formed 402 as is known in the art. The ingot is then embedded 404 in polycrystalline material to form a composite ingot. In an embodiment, the single crystal silicon ingot is positioned at a desired location in silicon powder, which is then sintered to form the polycrystalline portion 106 of the composite ingot. The composite ingot is then sliced 406 into wafers. Other suitable methods to make the composite wafer 202, 302 may also be used.

FIG. 5 is a flow chart that describes one use to which the composite wafer 202, 302 can be put: as a test wafer. Test wafers are used to characterize the effectiveness of a process, such as an etching process, a film deposition process, a chemical mechanical planarization (CMP) process, a lithographic process, or other processes. The wafer is processed by semiconductor equipment as though it were a wafer on which devices are made, but is then tested afterwards to monitor the process and equipment. As these test wafers are not turned into salable product, it is desirable to keep their cost down.

As shown in FIG. 5, the composite test wafer is processed 502. After processing, the results of that process are measured in the single crystal portion 108 of the composite wafer 202, 302. For example, with the composite wafer 302 having an offset single crystal silicon portion 108, the effectiveness of the process from the center of the wafer almost all the way (or even all the way) to the edge of the wafer 302 may be measured without requiring that the wafer be entirely single crystal silicon. In such a way, much of the test wafer 302 may be a less expensive polysilicon portion 106 and the desired test results may still be achieved.

Composite wafers 202, 302 or substantially wholly polycrystalline wafers 102 may also be used as handling or dummy wafers in place of costly single crystal wafers. As the material of the polycrystalline wafer 102 itself may be the same as the material of the single crystal wafers (such as polysilicon v. single crystal silicon), the polycrystalline wafer 102 may act in substantially the same manner as single crystal wafers and thus may be used as a substitute.

For example, when designing equipment that mechanically handles wafers, handling wafers are used to test this equipment. Polycrystalline wafers 102, 202, 302 may be used to test equipment that moves wafers 102 into and out of processing equipment, to test how a wafer is held in place during processing by equipment, to test containers in which wafers are moved from place to place, and other handling activities.

Similarly, polycrystalline wafers 102, 202, 302 may be used as dummy wafers in processing equipment. Dummy wafers are wafers that are loaded into processing equipment along with wafers from which actual product is made. Both the dummy wafers and the other wafers are processed by the equipment. The dummy wafers are used to help ensure that correct processing of the actual wafers is achieved. For example, in a furnace the top several wafers and bottom several wafers may be dummy wafers, with the actual wafers from which product is made being in the middle of the furnace. The dummy wafers help ensure that flows of gases and temperatures of the actual are even and as desired; gas flows and temperatures at the extremes of the furnace where the dummy wafers are may fluctuate more than would be acceptable for processing. As single crystal wafers are not required in such situations, polycrystalline wafers 102, 202, 302 may be used.

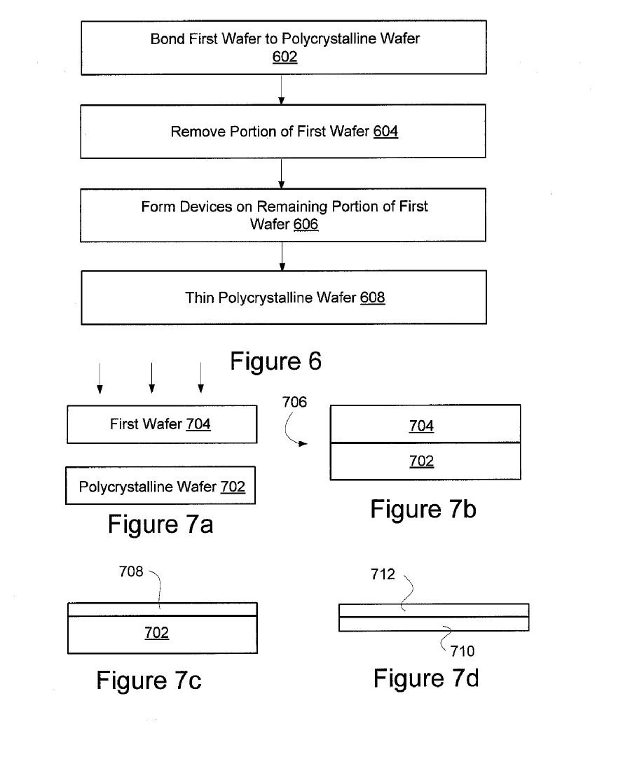

FIG. 6 is a flow chart that illustrates another use to which polycrystalline wafers 102 may be put: as a substrate in a bonded device. In a bonded device, a first wafer may be bonded 602 to a polycrystalline wafer. FIG. 7a is a cross sectional side view that illustrates this bonding 602. In the illustrated embodiment, a first wafer 704 is bonded 602 to a polycrystalline wafer 702, to form a bonded wafer. The polycrystalline wafer 702 may be substantially entirely polycrystalline silicon in an embodiment, may be a composite wafer such as those illustrated in FIGS. 2 and 3, or may be another type of polycrystalline wafer. The polycrystalline wafer 702 may comprise polysilicon or another material. The first wafer 704 may be a single crystal silicon wafer, or another type of wafer. For example, the first wafer 704 may comprise a group III-V material, SiGe material, or other materials in various embodiments. In another embodiment, the first wafer 704 may include a layer or region of insulating material as well as a layer or region of semiconducting material. In such an embodiment, the layer or region of insulating material may be between the semiconducting material layer or region and the polycrystalline wafer 702, to form a buried oxide layer, such as in semiconductor-on-insulator (SOI) wafers. Other types of wafers may also be bonded 602. The resulting bonded wafer 706 is shown in FIG. 7b. Note that while bonding 602 a wafer to another wafer is discussed, a wafer may be bonded to a portion of a wafer, a die, or other pieces of material in other embodiments.

Returning to FIG. 6, a portion of the first wafer 704 is removed 604. FIG. 7c is a cross sectional side view that illustrates the remaining portion 708 of the first wafer 704 on the polycrystalline 602 wafer. The portion of the first wafer 704 may be removed 604 by any suitable method, such as grinding, cleaving the first wafer 704 on a cleavage plane, or other methods.

Referring again to FIG. 6, devices may be formed 606 on the remaining portion 708 of the first wafer to result in a device layer 712. These devices may include transistors or other structures. For example, an entire microprocessor may be formed 606 on the device layer 712. The device layer 712 may include multiple layers of structures, as well as the remaining thinned portion 708 of the first wafer 704. At this point, the polycrystalline wafer 702 may provide mechanical support during formation 606 of the devices. For example, the polycrystalline wafer 702 may have a thickness of about 770 microns, while the device layer 712 is only a few microns thick. Other thicknesses may also be used in other embodiments.

Returning once more to FIG. 6, the polycrystalline wafer 702 is thinned 608. FIG. 7d is a cross sectional side view that illustrates the thinned polysilicon wafer 710. While the thicker wafer 702 may be useful in providing mechanical support during processing, the wafer 702 may be thinned 608 and diced into individual dies, such as microprocessor dies. In such an embodiment, the die has a device layer on a polycrystalline layer.

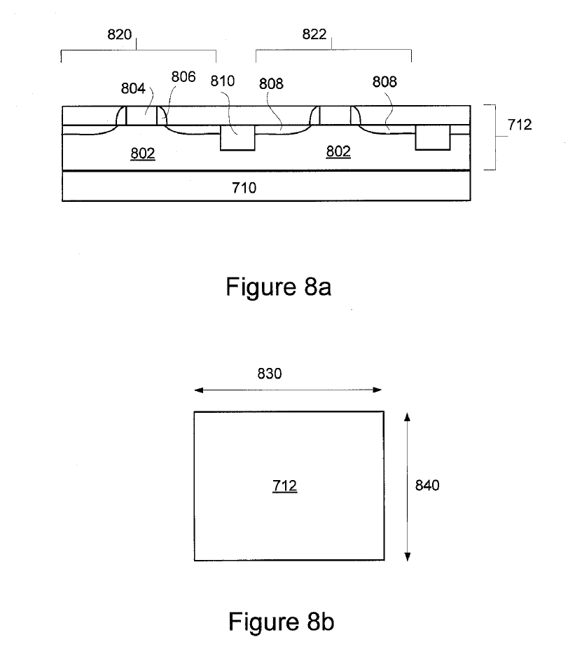

FIG. 8a is a cross sectional side view that illustrates one embodiment of a die with devices formed 606 on the bonded wafer 706. In the illustrated embodiment, there are two transistors 820, 822 shown. The transistors 820, 822 are formed on a semiconducting region 802, which may be, for example, single crystal silicon, SiGe, a group III-V material, or another material. The semiconducting region 802 is on the thinned polycrystalline layer 710. There may be additional regions between the semiconducting region 802 and the polycrystalline layer 710, such as an insulating region. Transistors 820 and 822 each has a gate 804, spacers 806, and source and drain regions 808. Trench isolation regions 810 separate the transistors 820, 822. The transistors 820, 822, the semiconducting region 802, and an insulating layer (if included) between the semiconducting region 802 and the thinned polycrystalline layer 710 may all be considered part of the device layer 712. While illustrated as planar transistors 820, 822 in FIG. 8a, the device layer 712 may include other types of devices, including non-planar transistors, quantum well channel transistors, or other active or passive devices.

FIG. 8b is a top view of the die of FIG. 5a. As seen in FIG. 5b, the die with the device layer 712 on top of the polycrystalline layer 710 has a width 830 and a length 840. The polycrystalline layer 7l0 is substantially coextensive in area with the device layer 712, so has the same width 830 and length 840 (or other dimensions for other, non-rectangular shapes). Thus, the die may have a device layer 712 with whatever material is most suitable, with an underlying polycrystalline layer 710 that reduces expense. In an embodiment, the device layer 712 is formed on single crystal silicon, while the polycrystalline layer 710 consists substantially of less expensive polysilicon.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A semiconductor die, comprising:
a bottom polycrystalline layer being substantially coextensive with an area of the die; and
a device layer on the polycrystalline layer, the device layer including a plurality of transistors.

2. The device of claim 1, wherein the bottom polycrystalline layer is polycrystalline silicon.

3. The device of claim 2, wherein the device layer comprises a group III-V material region as a substrate for the plurality of transistors.

4. The device of claim 2, wherein the device layer comprises a single crystal silicon region as a substrate for the plurality of transistors.

5. The device of claim 1, wherein the device layer comprises an insulating layer and a semiconducting region on the insulation layer, the semiconducting region being a substrate for the plurality of transistors.

6. The device of claim 1, wherein the die is a microprocessor die.

7. A method comprising:
using a wafer comprising a polycrystalline portion, the polycrystalline portion extending from a top to a bottom of the wafer, in semiconductor processing equipment, the wafer being used as one of the group consisting of a test wafer, a handling wafer, and a dummy wafer.

8. The method of claim 7, the wafer consists substantially of polysilicon.

9. The method of claim 7, wherein the wafer is a composite wafer that comprises a single crystal silicon portion embedded within a polysilicon portion.

10. The method of claim 9, wherein the wafer has a substantially circular shape, the single crystal silicon portion has a substantially circular shape, and the single crystal silicon portion is substantially centered within the wafer.

11. The method of claim 9, wherein the wafer has a substantially circular shape, the single crystal silicon portion has a substantially circular shape, and the single crystal silicon portion is offset within the wafer.

12. The method of claim 9, wherein the wafer is used as a test wafer, with measurements taken from the single crystal portion to monitor a process.

13. A method comprising:
bonding a semiconductor material to a polycrystalline wafer;
thinning the semiconductor material; and
forming a plurality of devices on the semiconductor material.

14. The method of claim 13, wherein the polycrystalline wafer consists substantially of polysilicon.

15. The method of claim 14, wherein the semiconductor material consists substantially of single crystal silicon.

16. The method of claim 15, wherein forming a plurality of devices comprises forming a microprocessor, and further comprising dicing the bonded wafers into dies.

17. A wafer, comprising:
a polycrystalline portion having a thickness that is the same as the thickness of the wafer; and
a single crystal portion having a thickness that is the thickness of the wafer, the single crystal portion taking up at least 15% of the volume of the wafer.

18. The wafer of claim 17, wherein the polycrystalline portion consists substantially of polysilicon and the single crystal portion consists substantially of single crystal silicon.

19. The wafer of claim 17, wherein the single crystal portion is substantially surrounded by the polycrystalline portion, the single crystal portion has a circular shape and the single crystal portion is offset from a center of the polycrystalline portion.

20. The wafer of claim 19, wherein the single crystal portion extends from a center of the wafer to adjacent an edge of the wafer.

21. The wafer of claim 17, wherein the polycrystalline portion takes up at least 25% of the volume of the wafer.
